(19) United States
(12) Patent Application Publication
(10) Pub. No.: US 2023/0186191 A1
(43) Pub. Date: Jun. 15, 2023

(54) Machine Management Based on Battery Status

(71) Applicant: Caterpillar Global Mining Equipment LLC, Denison, TX (US)

(72) Inventor: Cameron Thomas Lane, Oro Valley, AZ (US)

(73) Assignee: Caterpillar Global Mining Equipment LLC, Denison, TX (US)

(21) Appl. No.: 17/549,275

(22) Filed: Dec. 13, 2021

(51) Int. Cl. G06Q 10/06; G01R 31/392; G01R 31/371

(52) U.S. Cl. CPC G06Q 10/06311; G01R 31/392; G01R 31/371

(57) ABSTRACT

The present disclosure relates to batteries health across a fleet of machines. The battery life on a machine varies significantly according to work applications. A site has a plurality of the same machine working in various applications to fulfill a productivity requirement. More particularly, the present disclosure pertains to a balancing state of health (SoH) of batteries across a fleet of machines. The harshness of the various machine applications on a given work site is determined using a site-wide model. The model proactively tracks the work history and current battery state of health of each machine to determine appropriate assignments such that the machines rotate through the various applications on a periodic basis. Additionally, the model ensures a sufficient state of health of the battery to complete the assigned task. The reduced battery life results in downtime troubleshooting a perceived problem along with the associated additional cost. The balancing battery life across the fleet results in more consistent operation.

### TECHNICAL FIELD

The present disclosure generally relates to the balancing of battery state of health (SoH) across a fleet of mobile machines at a worksite, and in particular, to the automated assignment and mobilization of mobile machines to complete worksite tasks based on a battery status of the mobile machine.

### BACKGROUND

A mobile machine may be, for example, a self-propelled vehicle having a work implement or tool operatively connected thereto to perform work, or a vehicle that is capable of hauling material or people. For example, such mobile machines may be construction machines such as bulldozers, wheel loaders, graders, compaction machines, off-highway trucks, and other earth-moving equipment or construction equipment typically found at a worksite. When a work project is in process, various mobile machines perform multiple tasks each day at different locations at the worksite. For example, an excavator may excavate a trench at one location on one day, and at another location three days later. In between, a haul truck may haul away the excavated material from the trenches.

Some task assignment may be accomplished in a programmatic or semi-programmatic fashion. For example, U.S. Pat. No. 7,415,333 (hereinafter, “the '333 patent”) describes grading potential missions according to the severity of environmental stress expected to be experienced by a fleet of vehicles while completing the mission. The potential missions are generated and assigned based on use and maintenance data of the vehicles and environmental data. Once the potential missions are generated, they are assigned to vehicles according to a likelihood that the vehicle will reliably complete the mission.

While the system described in the '333 patent addresses a specific scenario involving assigning missions to a fleet of vehicles based on external environmental factors such as weather, the system is not useful for the assignment and mobilization of mobile machines on a worksite to complete worksite tasks while balancing battery SoH across the fleet. For example, although the system described in the '333 patent accounts for how weather conditions affect battery performance, the system does not evaluate how worksite tasks themselves affect battery SoH. Thus, the system described in the '333 patent is prone to error when assigning worksite tasks to one or more mobile machines and is not configured to optimize battery SoH across the fleet.

Example systems and methods of the present disclosure are directed toward overcoming the deficiencies described above.

### SUMMARY

According to a first aspect, a sitewide controller includes one or more processors and non-transitory computer-readable media storing computer-executable instructions. The computer-executable instructions, when executed by the one or more processors, cause the one or more processors to perform operations. The operations include identifying one or more machines associated with a worksite. The operations also include determining a first state-of-health (SoH) of a first battery associated with a first machine. The operations further include determining a second SoH of a second battery associated with a second machine. The operations further include identifying one or more worksite tasks to be performed at the worksite. The operations further include determining, for each task of the one or more worksite tasks, a first predicted impact on the first SoH and a second predicted impact on the second SoH. The operations further include assigning, based at least in part on the first SoH, the second SoH, the first predicted impact corresponding to a first task of the one or more worksite tasks, and the second predicted impact corresponding to a second task of the one or more worksite tasks, the first task to the first machine, wherein assigning the first task to the first machine indicates a lower predicted impact on the first SoH. The operations further include assigning, based at least in part on the first SoH, the second SoH, the first predicted impact corresponding to the first task, and the second predicted impact corresponding to the second task, the second task to the second machine. Assigning the second task to the second machine indicates a lower predicted impact on the second SoH. The operations further include generating a first task command indicating a worksite task corresponding to the first machine. The operations further include generating a second task command indicating a worksite task corresponding to the second machine. The operations additionally include sending, to the first machine, the first task command indicating the first worksite task. The operations additionally include sending, to the second machine, the second task command indicating the second worksite task.

According to further aspect, a method includes identifying, by one or more processors, one or more machines associated with a worksite. The method also includes determining, by the one or more processors, a first state-of-health (SoH) of a first battery associated with a first machine. The method further includes determining, by the one or more processors, a second SoH of a second battery associated with a second machine. The method further includes identifying, by the one or more processors, one or more worksite tasks to be performed at the worksite. The method further includes determining, by the one or more processors, for each task of the one or more worksite tasks, a first predicted impact on the first SoH and a second predicted impact on the second SoH. The method further includes assigning, by the one or more processors and based at least in part on the first SoH, the second SoH, the first predicted impact corresponding to a first task of the one or more worksite tasks, and the second predicted impact corresponding to a second task of the one or more worksite tasks, the first task to the first machine. Assigning the first task to the first machine indicates a lower predicted impact on the first SoH. The method further includes assigning, by the one or more processors and based at least in part on the first SoH, the second SoH, the first predicted impact corresponding to the first task, and the second predicted impact corresponding to the second task, the second task to the second machine. Assigning the second task to the second machine indicates a lower predicted impact on the second SoH. The method further includes generating, by the one or more processors, a first task command indicating a worksite task corresponding to the first machine. The method further includes generating, by the one or more processors, a second task command indicating a worksite task corresponding to the second machine. The method also includes sending, by the one or more processors to the first machine, the first task command indicating the first worksite task. The method also includes sending, by the one or more processors to the second machine, the second task command indicating the second worksite task.

According to further aspect, a method includes identifying, by one or more processors, one or more machines associated with a worksite. The method also includes determining, by the one or more processors, a first state-of-health (SoH) of a first battery associated with a first machine. The method further includes determining, by the one or more processors, a second SoH of a second battery associated with a second machine. The method further includes identifying, by the one or more processors, one or more worksite tasks to be performed at the worksite. The method further includes determining, by the one or more processors, for each task of the one or more worksite tasks, a first predicted impact on the first SoH and a second predicted impact on the second SoH. The method further includes assigning, by the one or more processors and based at least in part on the first SoH, the second SoH, the first predicted impact corresponding to a first task of the one or more worksite tasks, and the second predicted impact corresponding to a second task of the one or more worksite tasks, the first task to the first machine. Assigning the first task to the first machine indicates a lower predicted impact on the first SoH. The method further includes assigning, by the one or more processors and based at least in part on the first SoH, the second SoH, the first predicted impact corresponding to the first task, and the second predicted impact corresponding to the second task, the second task to the second machine. Assigning the second task to the second machine indicates a lower predicted impact on the second SoH. The method further includes generating, by the one or more processors, a first task command indicating a worksite task corresponding to the first machine. The method further includes generating, by the one or more processors, a second task command indicating a worksite task corresponding to the second machine. The method also includes sending, by the one or more processors to the first machine, the first task command indicating the first worksite task. The method also includes sending, by the one or more processors to the second machine, the second task command indicating the second worksite task.

### BRIEF DESCRIPTION OF DRAWINGS

FIG. 1 illustrates an example system including example mobile machines configured for receiving task commands and completing worksite tasks according to examples of the present disclosure.

FIG. 2 illustrates a flowchart that depicts an example method for sending to the mobile machines a task command to perform worksite tasks according to examples of the present disclosure.

FIG. 3 illustrates a flowchart that depicts an example method for assigning one or more mobile machines at a worksite to corresponding tasks for a time period according to examples of the present disclosure.

FIG. 4 illustrates a flowchart that depicts an example method for assigning a worksite task to a particular mobile machine and identifying one or more other worksite tasks to be completed according to examples of the present disclosure.

FIG. 5 illustrates a flowchart that depicts an example method for receiving a task command, completing the task, and indicating that the task has been completed according to examples of the present disclosure.

FIG. 6 illustrates exemplary factors considered when determining an impact on battery SoH according to examples of the present disclosure.

FIG. 7 is a block diagram of an example sitewide controller that implements worksite tasks of the mobile machines according to examples of the present disclosure.

FIG. 8 is a block diagram of an example electronic device for balancing battery SoH across a fleet of mobile machines at a worksite according to examples of the present disclosure.

The following detailed description of the drawings provides references to the accompanying figures. In the figures, the left-most digit(s) of a reference number identifies the figure in which the reference number first appears. The use of the same reference numbers in different figures indicates similar or identical items. The systems depicted in the accompanying figures are not to scale, and components within the figures may be depicted not to scale with each other.

### DETAILED DESCRIPTION

This disclosure describes technology related to balancing battery SoH across a fleet of mobile machines at a worksite. A mobile machine may be, for example, an autonomous or semi-autonomous self-propelled vehicle or non-autonomous, staffed vehicle that is configured to perform one or more operations associated with a given industry such as paving, excavation, mining, construction, farming, transportation, oil and gas, manufacturing, or any other suitable industry.

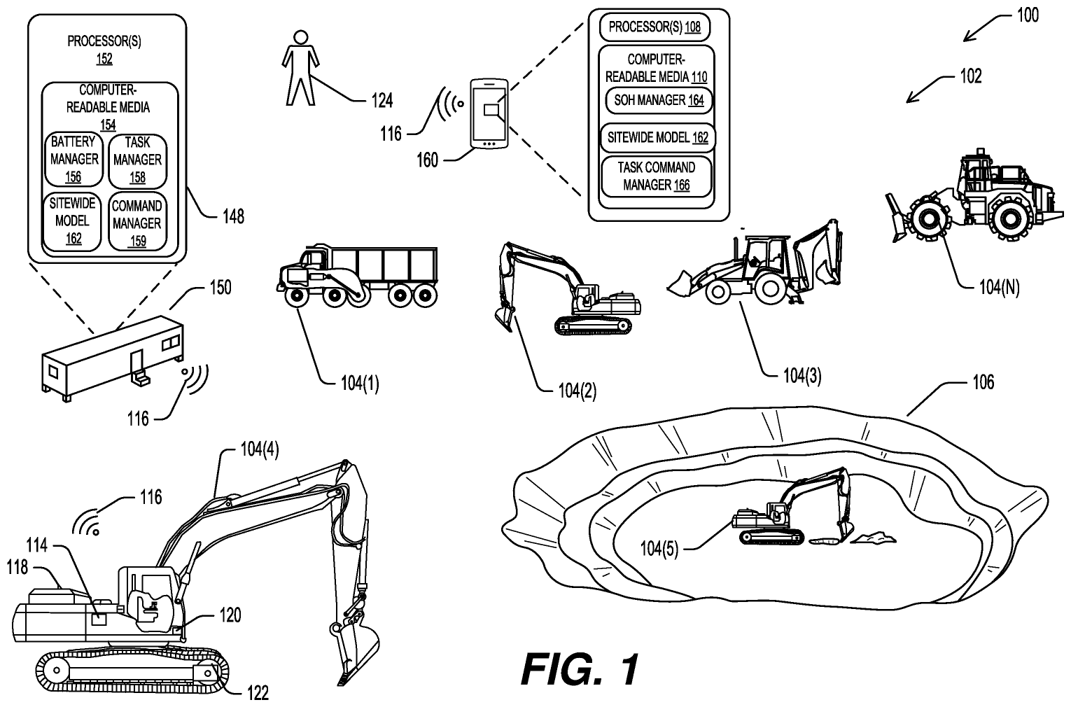

FIG. 1 illustrates an example system 100 disposed at an example worksite 102. The system 100 includes one or more mobile machines 104(1), 104(2), 104(3), . . . 104(N) (hereinafter referred to individually as “mobile machine 104” or collectively as “mobile machines 104”) that are configured for performing worksite tasks, according to examples of the present disclosure. The mobile machines 104, although depicted here as comprising at least a haul truck 104(1), excavator 104(2), backhoe 104(3), etc. may be any suitable type of machine or tool that may be used in any variety of industries, such as construction, mining, farming, transportation, security services, oil and gas, etc. For example, the mobile machine 104 may be any suitable machine, such as any type of loader, dozer, dump truck, skid loader, excavator, compaction machine, backhoe, combine, crane, drilling equipment, tank, trencher, tractor, grading machine, articulated truck, asphalt paver, backhoe loader, cold planer, drill, forest machine, hydraulic mining shovel, material handler, motor grader, off-highway truck, pipelayer, road reclaimer, track loader, underground machine, utility vehicle, wheel loader, tanker (e.g., for carrying water or fuel), combinations thereof, or the like. The mobile machines 104 are configured to receive an indication of a desired movement or mobilization corresponding to completion of a worksite task and move according to the desired movement. In some cases, the mobile machines 104 are autonomous and move automatically according to the desired movement. In other cases, the mobile machines 104 are dispatched according to the desired movement, such as in the case of the mobile machines 104 being non-autonomous. In the case that the mobile machines 104 are autonomous or semi-autonomous, the mobile machines 104 are further configured to determine a path to automatically travel to various locations at the worksite 102. Furthermore, the mobile machines 104 are configured to, individually or in cooperation with each other, perform a commercial or industrial task, such as mining, construction, energy exploration and/or generation, manufacturing, transportation, agriculture, or any task associated with other types of industries. Although six mobile machines 104 are depicted here, it should be understood that there may be any suitable number of mobile machines 104 at a worksite 102, according to examples of the disclosure.

The worksite 102 includes a variety of different locations in which or to which the mobile machines 104 may be maneuvered, staged, maintained, stored, parked, supplied, and/or used to perform work. The worksite 102 may include, for example, a work area 106 at which the mobile machines 104 engage in work activities, such as digging dirt, distributing asphalt, redistributing gravel, harvesting wheat, or the like. Although the work area 106 is depicted as an open pit mine, it should be understood that the work area 106 may be any suitable location in any suitable application, such as construction, mining, farming, transportation, or the like. For example, the work area 106 may be in the form of a paving site, an industrial site, a factory floor, a building construction site, a road construction site, a quarry, a building, a city, combinations thereof, or the like.

The mobile machines 104 may include a controller 114 thereon that controls the worksite task functionality of the mobile machine 104. The mobile machine 104 may receive wireless signal(s) 116 via an antenna 118 that is operably connected to the controller 114. The wireless signal 116, as received by the mobile machine 104 may carry instructions and/or one or more commands for the mobile machine 104 to complete worksite tasks within the worksite 102. For example, the wireless signal 116 may include an indication of a particular location at the worksite 102 to which the mobile machine 104 is to relocate. The controller 114 and/or other associated electronic hardware of the mobile machine 104 may process the wireless signal 116 to determine the location within the worksite 102 to which the mobile machine 104 is to be relocated. The controller 114 may use any variety of sensors 120 of the mobile machine 104 to control a propulsion system 122 of the mobile machine 104 to relocate the mobile machine 104 to a desired location at the worksite 102, such as the location indicated by way of the wireless signal 116. Although the controller 114, the antenna 118, the sensors 120, and the propulsion system 122 are depicted on the excavator 104(4), it should be understood that each of the mobile machines 104 may have their own controllers 114, antennas 118, sensors 120, and propulsion systems 122.

The sensors 120 may include any suitable number and/or type of sensors 120 that generate sensor signals that are received and processed by the controller 114 or other electronic hardware of the mobile machine 104 to indicate features (e.g., ground conditions, built structures, location, etc.) surrounding the mobile machine 104 and/or the current location of the mobile machine 104. The sensors 120 may include, for example, any one or more of Light Detection and Ranging (LIDAR) sensors, Radio Detection and Ranging (RADAR) sensors, Sound Detection and Ranging (SONAR) sensors, Global Navigation Satellite Sensors (GNSS) location sensors (e.g., Global Positioning Satellite (GPS) sensor, etc.), magnetic sensors (e.g., compass, etc.), inertial sensors (e.g., accelerometers, magnetometers, gyroscopes, etc.), cameras (e.g., RGB, IR, intensity, depth, time of flight, etc.), microphones, wheel encoders, environment sensors (e.g., temperature sensors, humidity sensors, light sensors, pressure sensors, etc.), combinations thereof, or the like. The sensors 120 may include multiple instances of each of these or other types of sensors 120. The controller 114 is configured to receive the sensor signals from the sensors 120 and process those sensor signals to identify the surrounding conditions, current location, and/or features proximal to the mobile machine 104. Different mobile machines 104 may have the same sensors 120 or different sensors 120.

The propulsion system 122, although depicted as a chain drive or continuous track of the excavator 104(4) may be any suitable drive system of the mobile machines 104. The propulsion system 122, as discussed herein may include an engine, e.g., an internal combustion, hybrid or other engine (not shown), electric motor (not shown), a steering system (not shown), and/or a transmission (not shown) of the mobile machine 104. The controller 114 is configured to control various aspects of the propulsion system 122 of the mobile machine 104, such as velocity or speed, direction, gears, etc. In general, the controller 114 may be configured to control the movement of the mobile machine 104 by controlling various components (e.g., transmission, steering, etc.) of the propulsion system 122 of the mobile machine 104, such as in a similar manner as a human operator of the mobile machine 104 may control the propulsions system 122. For example, the controller 114 may operate various components of the propulsion system 122 in a fly-by-wire mechanism.

By using sensor signals from the sensors 120 and based at least in part on a desired location corresponding to a worksite task of the mobile machine 104, the controller 114 is configured to cause the mobile machine 104 to move to reach the desired location, such as the work area 106. The controller 114 uses the sensors 120 to identify its present position, such as by using GPS data, and/or to identify hazards in its proximity, such as by using camera/imager data and/or LIDAR data. For example, senor signals from a sensor 120 in the form of a LIDAR may indicate that the mobile machine 104 that is being autonomously moved may be proximate to a hazard in the form of another mobile machine 104. In this case, the controller 114 may control the mobile machine 104 by controlling its propulsion system 122 such that its pathway avoids a collision with the other mobile machine 104 as the mobile machine 104 is moved to its target location.

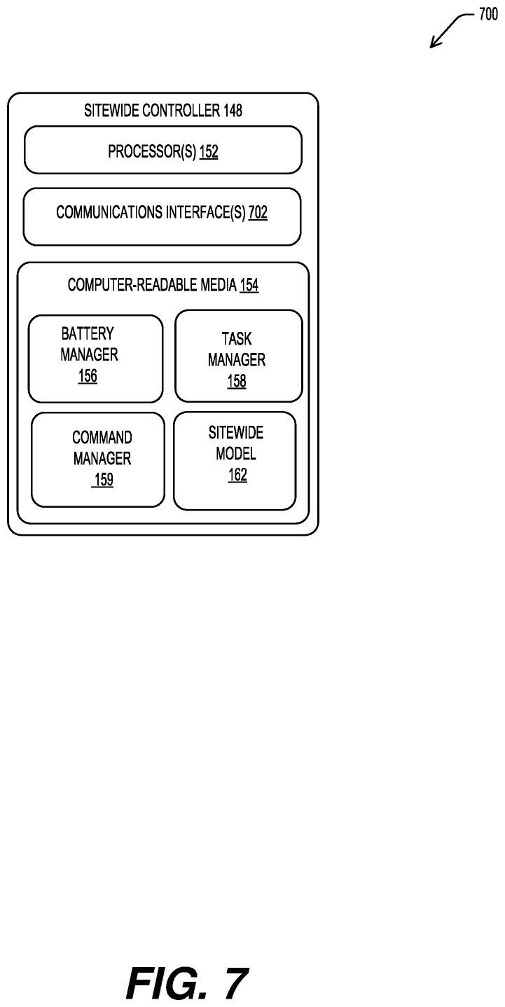

The system 100 may include an electronic device 160 configured to generate the wireless signal 116 that enables the transmission of a task command to the controller 114 of the mobile machine 104 via the antenna 118. The electronic device 160 may have a software application running thereon to instruct the mobile machine 104. For example, the electronic device 160, with the software application running thereon, may generate the task command and transmit the same via the wireless signal 116. The electronic device 160 may be controlled by an operator 124 (e.g., a worksite 102 manager, construction worker, miner, farmer, paver, etc.) in some cases. Thus, the electronic device 160, with the software application running thereon, may receive input from the operator 124, such as via one or more human machine interface(s) (HMIs), to proceed with generating the task command. The human operator 124 may provide any variety of parameters, corresponding to desired operating characteristics of the mobile machine 104 for the completion of the worksite task, such as destination location, predetermined intervals for sending battery SoH data, etc. These parameters may be encoded by the electronic device 160 into a task command that is transmitted to the one or more mobile machines 104 via the wireless signal 116. In some cases, the electronic device 160 may be communicatively connected to a sitewide controller 148 such as one that is housed in a control center 150 disposed at the worksite 102. The sitewide controller 148 is configured to perform similar functions to those performed by the electronic device 160, as described below. The sitewide controller 148 will be described in greater detail below with respect to FIG. 7.

The electronic device 160, with the software application operating thereon, is further configured to communicate with the controller 114 of the mobile machine 104 to receive a worksite task completion notification. Thus, the mobile machine 104, after completing an assigned worksite task, sends a notification indicating completion of the assigned worksite task, such as via the wireless signals 116, to the electronic device 160 that commanded the worksite task of the mobile machine 104. The electronic device 160, upon receiving the indication of completion of the worksite task, is further configured to display a task completion notification on a display of the electronic device 160. Such a task completion notification is configured for viewing by the operator 124, for example.

The electronic device 160, as depicted herein, is separate from the mobile machines 104. In other words, in aspects of the disclosure, the electronic device 160 is not physically wired to the mobile machines 104 or physically incorporated into or attached to the electrical wiring of the mobile machines 104. Rather, the electronic device 160 communicates with the mobile machine 104 wirelessly. In some instances, the communications between the electronic device 160 and the mobile machines 104 may be via protocol based communications (e.g., direct Wi-Fi, Wi-Fi, the Internet, Bluetooth, etc.), and in other instances, the communications may be non-protocol-based communications (e.g., remote control). In examples of the disclosure, the system 100 with communications between one or more electronic devices 160 and one or more mobile machines 104 may result in a worksite level network, such as a local area network (LAN) or a wide-area network (WAN). In alternative examples, the electronic device 160 may be incorporated in and/or otherwise hardwired to the mobile machine 104.

Although the electronic device 160 is depicted herein as a smartphone, it should be understood that the electronic device 160 may be any suitable electronic device. For example, the electronic device 160 may be a computer, a mobile device, a server, a tablet computer, a notebook computer, a handheld computer, a workstation, a desktop computer, a laptop, any variety of user equipment (UE), a network appliance, an e-reader, a wearable computer, a network node, a microcontroller, a smartphone, or another computing device. The software application that operates on the electronic device 160 to enable it to control the worksite task functionality of the mobile machines 104 may be downloaded to the electronic device 160 from any suitable source, such as a commercial app downloading website, USB, or the like.

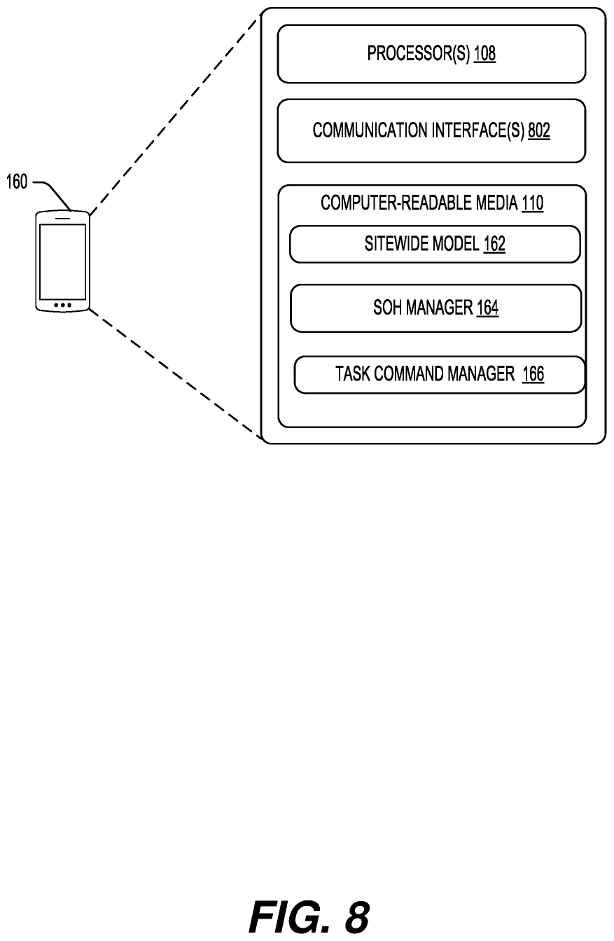

The electronic device 160 comprises a sitewide model 162 and a SoH manager 164 (both of which are also shown schematically in FIG. 8). The sitewide model 162 is configured to track the various worksite tasks to be completed at the worksite 102, and the mobile machines 104 available to complete such worksite tasks. The sitewide model 162 grades, indexes, or otherwise compares the worksite tasks to be completed according to an energy requirement of the task and a harshness (i.e., expected battery SoH impact) of a given worksite task on the battery SoH of a mobile machine 104. The SoH manager 164 proactively determines the mobile machine 104 or mobile machines 104 having a battery SoH suited for an available task. Thus, being in communication with the SoH manager 164, the sitewide model 162 matches a mobile machine 104 to a particular worksite task.

The electronic device 160 further comprises a task command manager 166 (also shown schematically in FIG. 8). The task command manager 166 is configured to generate and disseminate task commands conducive for balancing battery SoH while completing worksite tasks at the worksite 102. Thus, the electronic device 160 (i.e., the task command manager 166) is, in some cases, configured to generate task commands for a single mobile machine 104 to perform one or more worksite tasks. In other cases, the task command manager 166 is configured to generate task commands for a number of mobile machines 104, such as all or some subset of all the mobile machines 104 at the worksite 102. The task command manager 166, in some examples, generates a task command for a single mobile machine 104 responsive to an interaction with the operator 124 or another electronic device 160. In other cases, the task command manager 166 generates a task command for two or more mobile machines 104 responsive to an interaction with the operator 124 or another electronic device 160. In either case, the task command may instruct the target mobile machine(s) 104 to perform worksite task(s) that at least include relocating the mobile machine(s) 104 from their current location(s) at the worksite 102 to new location(s) at the worksite 102.

In some cases, a task command generated by the task command manager 166 provides a worksite task location to which the recipient mobile machine 104 is to move. This worksite task location may be specified in any suitable manner, such as latitude and longitude coordinates, a worksite 102 specific coordinate system, feature identification (i.e., a task command may include instructions describing the location that the mobile machine 104 is to relocate to in order to perform the worksite task. In the case where a worksite task and/or location is referenced by a feature at the worksite (e.g., excavation pit 106), the task command manager 166 and/or the controller 114 may have access to a look-up table or other suitable mechanism that maps feature locations to a suitable coordinate system, such as latitude and longitude coordinates.

As discussed above, FIG. 1 illustrates a system including mobile machines 104 that are configured for receiving task commands and completing worksite tasks. FIG. 1 illustrates various mobile machines 104, including mobile machines 104 that are similar or identical to one another. The system of FIG. 1 includes a sitewide model 162 that tracks and leverages battery SoH of the mobile machines 104. The sitewide model 162 also indexes the harshness of a particular worksite task on battery SoH. Thus, the system illustrated in FIG. 1 allows, for example, an operator 124 utilizing the electronic device 160, to leverage the sitewide model 162 and assign mobile machines 104 to appropriate worksite tasks. In some alternative cases, the sitewide controller 148 is used to leverage the sitewide model 162.

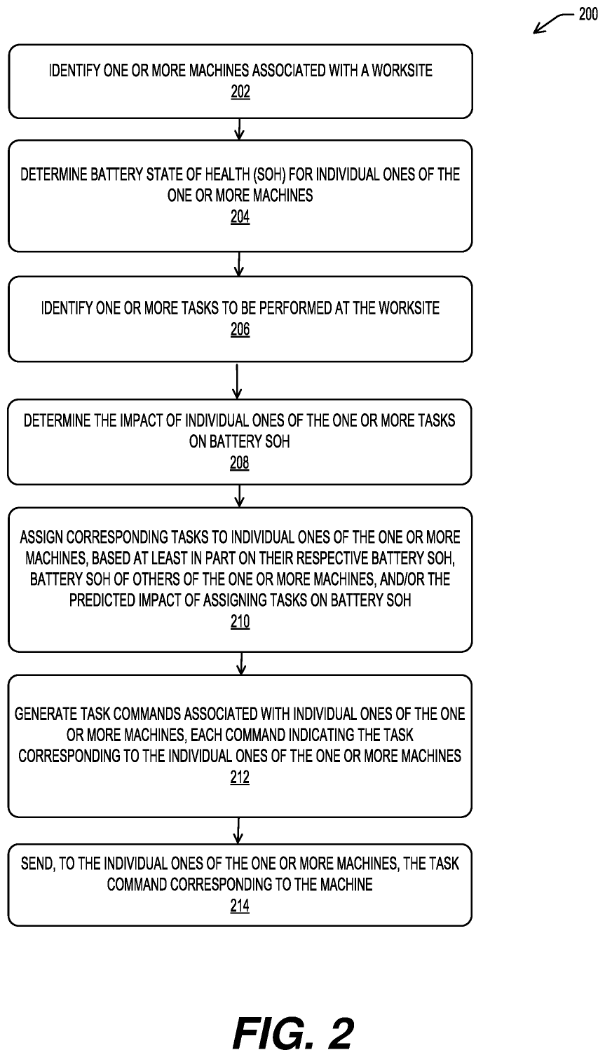

FIG. 2 illustrates a flowchart that depicts an example method 200 for sending to the mobile machines 104 of FIG. 1 a task command to perform worksite tasks, according to examples of the disclosure. The operations of method 200 may be performed by the sitewide controller 148 in cooperation with one or more entities of system 100.

At operation 202, the sitewide controller 148 identifies one or more mobile machines 104 associated with a worksite 102. In one non-limiting example, the sitewide controller 148 receives sensor data such as GPS coordinates of the mobile machines 104 and determines, based on known GPS coordinates of a perimeter of the worksite 102, that one or more mobile machines 104 are located within a threshold distance of the worksite 102. In this example, the sitewide controller 148 is further configured to request such sensor data, such as by sending a request for mobile machines 104 located within a threshold distance of the worksite 102 to provide their respective GPS coordinates. In another non-limiting example, the sitewide controller 148 accesses a lookup table, database, or other suitable mechanism that associates individual mobile machines 104 with the worksite 102, such as by associating a VIN number, chassis number, or other unique identifier with the worksite 102. In this example, the sitewide controller 148 communicates, via wireless signal 116, with the mobile machines 104 having unique identifiers associated with the worksite 102. In this way, the sitewide controller 148 confirms that those mobile machines 104 having unique identifiers associated with the worksite 102 are available to perform worksite tasks.

At operation 204, the sitewide controller 148 determines battery SoH for individual ones of the mobile machines 104. The sitewide controller 148 considers at least: the number of charge/discharge cycles a battery has undergone, battery charging/discharging C-rate, battery chemistry, the temperature of a battery during its previous use cycles, internal impedance, and the total energy charged/discharged by the battery (and any combination thereof) to determine battery SoH.

At operation 206, the sitewide controller 148 identifies one or more worksite tasks to be performed at the worksite 102. In one non-limiting example, the sitewide controller 148 has access to and retrieves data from a database table of pending worksite tasks. For example, the operator 124 may maintain a database of worksite tasks to be completed at the worksite 102. The pending worksite tasks are enumerated according to any suitable scheme, including completion date priority, task creation date, expected battery expenditure, etc. In at least some cases, the database of pending worksite tasks is stored in association with the sitewide model 162.

At operation 208, the sitewide controller 148 determines the impact of individual ones of the one or more tasks on battery SoH. The sitewide model 162 considers the harshness of the various machine applications on the worksite 102. In some examples, the impact on battery SoH is considered as an absolute quantity, i.e., the impact on battery SoH of a given task is expressed as an estimated energy expenditure. However, the sitewide model 162 proactively tracks work history and current battery SoH of each mobile machine 104. Therefore, in some examples, the impact on battery SoH is considered as a relative quantity. In other words, the impact on battery SoH of a given worksite task is compared to that of each other worksite task in order to determine appropriate assignments such that mobile machines 104 rotate through the various worksite tasks on a periodic basis. That is to say that worksite tasks are prioritized, at least in some cases, according to one or more considerations such as impact on battery SoH (i.e., harshness). In still other examples, the impact on battery SoH of an individual worksite task is expressed as a battery SoH threshold. The battery SoH threshold is expressed as a normalized percentage of remaining battery life, an equivalent amount of power left to be expended (e.g., 1 kW, 2 kW, 5 kW, 10 kW, etc.), an equivalent amount of fuel left to be consumed (e.g., 1 gallon, 5 gallons, 10 gallons, etc.) or any appropriate quantity conveying energy information. In such examples, a mobile machine 104 having a battery SoH below the battery SoH threshold is unsuitable for a particular task. In yet other examples, still, the impact on battery SoH is expressed as a percentage of new battery range. For example, a battery near the end of its life may only be able to deliver 80% of the energy of a new battery during one charge/discharge cycle.

At operation 210, the sitewide controller 148 assigns worksite tasks to be performed at the worksite 102 to individual ones of the one or more mobile machines 104. Assigning tasks to individual ones of the one or more mobile machines 104 includes balancing battery SoH across the fleet of mobile machines 104 via the sitewide model 162. Therefore, task assignments to individual ones of the one or more mobile machines 104 are based at least in part on the respective battery SoH of a particular mobile machine 104, the battery SoH of others of the one or more mobile machines 104 and/or the aggregate impact of assigning tasks on the fleet's battery SoH. In some examples, balancing battery SoH comprises assigning tasks to mobile machines 104 according to capability. For example, some tasks may require a mobile machine 104 with a new battery to complete them.

Generally, the sitewide controller 148 grades or otherwise compares each possible assignment permutation matching a mobile machine 104 to a worksite task. In some cases, this includes the sitewide controller 148 determining a first target battery SoH of the first battery upon completion of a first potential worksite task. Likewise, the sitewide controller 148 determines a second target battery SoH of the first battery upon completion of a second potential worksite task. In order to illustrate the permutations that exist in this example situation, imagine that a second mobile machine 104 is comparable and also available to complete the two potential worksite tasks. The sitewide controller 148 determines a third target battery SoH of the second battery upon completion of the second potential worksite task. The sitewide controller makes the same determination regarding a fourth target battery SoH of the second battery upon completion of the first potential worksite task. The sitewide controller 148 determines which mobile machine 104 to assign to which worksite task by comparing the energy consumed by the first battery and the second battery in completing each worksite task. Thus, the sitewide controller 148 determines a first difference between the first target battery SoH and the third target battery SoH and second difference between the second target battery SoH and the fourth target battery SoH.

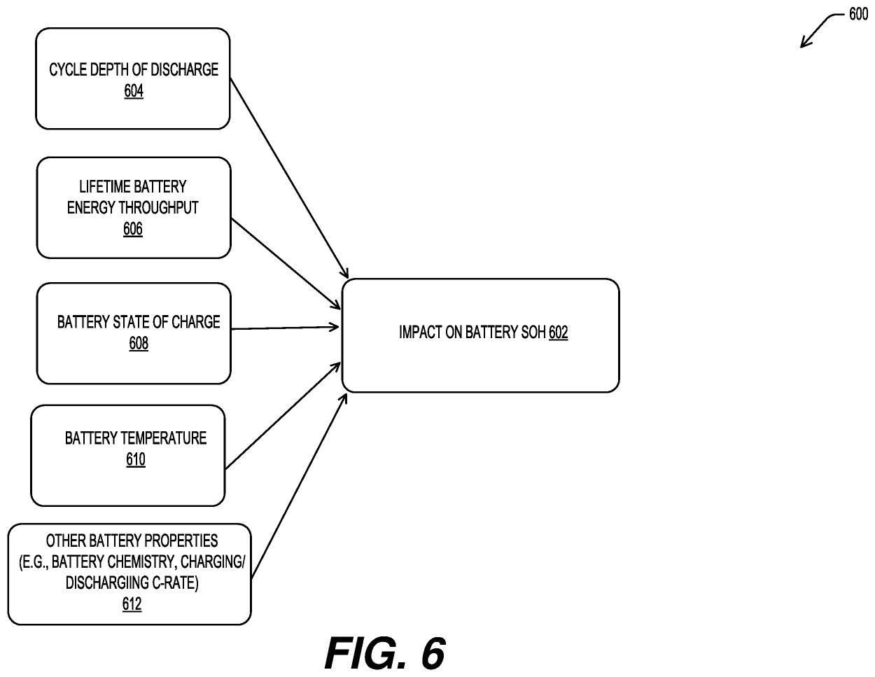

The sitewide model 162 matches mobile machines 104 with applications according to a balancing of battery SoH. With brief reference to FIG. 6, the sitewide model 162 considers at least cycle depth of discharge (DoD), lifetime battery energy throughput, battery state of charge (SoC), battery temperature, and other battery properties (such as a planned battery replacement timeframe) to determine a potential impact on battery SoH. In some examples, battery SoC is calculated using one or more of coulomb counting, discharge testing (e.g., employing a discharge curve to compare voltage to an equivalent SoC), and Kalman filters. Thus, battery SoC is calculated via robust methods whereby measurement noise and other error propagators such as temperature effects, calibration errors, current fluctuations and the like are filtered out. In some cases, the DoD is calculated and the complement thereof taken to define a battery SoC. In other cases, the reverse process is employed. For each application to which one or more individual mobile machines 104 are to be matched, the sitewide model 162 considers the energy requirement for a completed cycle and the state of health impact on the cycle.

Returning now to FIG. 2, the worksite tasks are normalized such that comparable mobile machines 104 are interchangeable with regard to assignment of tasks. Therefore, in some cases, the particular mobile machine 104 to which a worksite task is assigned may be specified at operation 210, or alternatively, the sitewide controller 148 selects a particular mobile machine 104 from a subset of comparable mobile machines 104 in an inventory of the worksite 102. For example, if the worksite task is to be completed by a haul truck and there are four different, but comparable haul trucks at the worksite 102, the sitewide controller 148 chooses one of the haul trucks according to any suitable factor, such as the haul truck that has been more recently recharged, the haul truck that is nearest to the location of the worksite task to be completed, etc. (battery SoH being equal among the available haul trucks). In the case that a mobile machine 104 is selected from a subset of comparable mobile machines 104, the sitewide controller 148 queries each mobile machine 104 of the subset of comparable mobile machines 104 for suitable data to select one mobile machine 104 over the other comparable mobile machines 104. In at least some cases, the sitewide controller 148 has access to and consults a table of suitable deciding factors (e.g., last recharge time, distance from a desired worksite location, etc.). The sitewide controller 148 queries each mobile machine 104 of the subset of comparable mobile machines 104 for data corresponding to the deciding factors until a suitable mobile machine 104 is selected.

At operation 212, the sitewide controller 148 generates task commands to be transmitted to individual ones of the one or more mobile machines 104. The generated task commands correspond to the worksite tasks to be performed by each mobile machine 104. Each task command includes one or more parameters associated with the worksite task that is to be completed by each mobile machine 104. Each task command includes one or more data packets with header portions that indicate at least the destination mobile machine 104 is being directed to by those data packets. A payload portion of the data packets includes an indication of the various parameters associated with the worksite task. The parameters include at least an indication of a target battery SoH and a target battery recharging time for the mobile machine 104 upon completion of the worksite task. In other words, the payload portion of the data packets comprising the task command at least communicates to the mobile machines 104: (1) target battery SoH and (2) target battery recharge. Thus, each task command serves as a formatted unit of data communicating pertinent information about worksite tasks to the mobile machines 104.

At operation 214, the sitewide controller 148 sends to individual ones of the one or more mobile machines 104 corresponding worksite tasks. The task command is encoded and/or modulated onto the wireless signal 116 that is received by the antenna 118 of the mobile machine 104. The controller 114 receives the wireless signal 116 and decodes and/or demodulates the wireless signal 116 to identify the task command. In some cases, the electronic device 160, being in communication with the sitewide controller 148, requests the task command, such as based upon operator 124 input. The sitewide controller 148 transmits the task command via the wireless signal 116. In such cases, the controller 114 of the mobile machine 104 subsequently receives the task command from the sitewide controller 148 and decodes and/or demodulates the wireless signal 116 to identify the task command.

As discussed above, FIG. 2 depicts an example method 200 for sending to the mobile machines 104 a task command to perform worksite tasks. Method 200 includes identifying the one or more mobile machines 104 associated with the worksite 102 and determining their respective battery SoH. Method 200 further includes identifying one or more worksite tasks to be performed at the worksite 102 and determining an expected impact on battery SoH of each worksite task. The task commands that are sent to the mobile machines 104 indicate worksite task assignments that consider the abovementioned impact on battery SoH.

It should be noted that some of the operations of method 200 may be performed out of the order presented, with additional elements, and/or without some elements. Some of the operations of method 200 may further take place substantially concurrently and, therefore, may conclude in an order different from the order of operations shown above. It should also be noted that in some cases, there may be other components of the system 100 involved in one or more of the operations, as described herein.

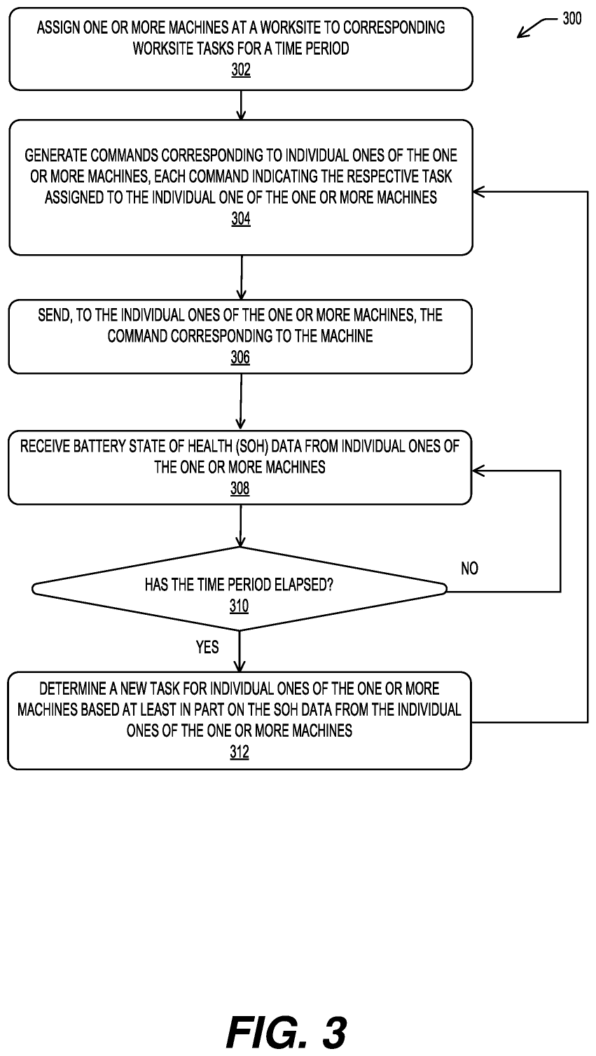

FIG. 3 illustrates a flowchart that depicts an example method 300 for assigning one or more mobile machines 104 at a worksite 102 to corresponding tasks for a time period, according to examples of the present disclosure. In some embodiments, the operations of method 300 are performed in cooperation with one or more entities of system 100, such as to assign one or more mobile machines 104 of FIG. 1 to perform corresponding tasks for a time period.

At operation 302, the sitewide controller 148 assigns one or more mobile machines 104 at a worksite 102 to corresponding worksite tasks for a time period. For example, the sitewide controller 148 employs the sitewide model 162 that balances battery SoH across a fleet of vehicles, such as in accordance with operation 210 of FIG. 2, to assign the one or more mobile machines 104 to corresponding worksite tasks. The time period for which individual mobile machines 104 are assigned to tasks is a variable characterizing how battery SoH should be balanced or otherwise stabilized across each mobile machine 104.

At operation 304, the sitewide controller 148 generates a task command corresponding to individual ones of the one or more mobile machines 104. The generated task commands indicate the respective worksite tasks assigned to each mobile machine 104. The task command includes one or more parameters associated with the worksite task that is to be completed by the mobile machine 104. Similar to the above discussion regarding operation 212, the task command includes one or more data packets with header portions that indicate at least the destination mobile machine 104 is being directed to and payload portions indicating the various parameters associated with the worksite task.

At operation 306, the sitewide controller 148 sends to individual ones of the one or more mobile machines 104 corresponding task commands. The task command is encoded and/or modulated onto the wireless signal 116 that is received by the antenna 118 of the mobile machine 104. The controller 114 receives the wireless signal 116 and decodes and/or demodulates the wireless signal 116 to identify the task command. In some cases, the electronic device 160, being in communication with the sitewide controller 148, requests the task command, such as based upon operator 124 input. The sitewide controller 148 transmits the task command via the wireless signal 116. In such cases, the controller 114 of the mobile machine 104 subsequently receives the task command from the sitewide controller 148 and decodes and/or demodulates the wireless signal 116 to identify the task command.

At operation 308, the sitewide controller 148 receives battery SoH data from each individual mobile machine 104. The sitewide controller 148 tracks the modes and/or operational status of all, or some, of the mobile machines 104 at the worksite 102. Thus, in some cases, the sitewide controller 148 receives battery SoH data from only those mobile machines 104 that are currently engaged in or have recently completed worksite tasks. In these cases, the controller 114 of the mobile machines 104 automatically sends battery SoH data to the sitewide controller 148 such as at predetermined intervals or upon the triggering of a SoH event (such as a determination that the time period for completing a worksite task has not yet elapsed, as discussed below with regard to operation 310). In some cases, the mobile machine 104 may be offline and may not have received and/or executed task commands. Thus, the sitewide controller 148 alternatively queries the battery SoH from any mobile machine 104 from which battery SoH data has not been received for a threshold time period by communicating with the controller 114 of the mobile machine 104. For example, SoH data indicating capacity to complete an available worksite task that is received from an offline mobile machine 104 may be interpreted to mean that the time period for performing worksite tasks needs to be recalculated. This battery SoH data is therefore used to modify and/or update the sitewide model 162 as discussed further below with regard to operation 310.

At operation 310, the sitewide controller 148 determines whether the time period has elapsed for which the mobile machine 104 is assigned to perform the worksite task. This determination is initiated at least in part by receiving the battery SoH data in operation 308. If the received SoH data is lower than a target SoH, then the time period is adjusted to compensate for such unanticipated stress on SoH. Alternatively, or in addition, the mobile machine 104 is flagged for having a potential battery issue and/or the worksite 102 is flagged to be inspected for being of greater harshness to battery SoH than expected. If the sitewide controller 148 determines that the time period for performing the worksite task has not elapsed (operation 310—No), the method 300 may reiteratively return to operation 308 where the mobile machine 104 automatically sends battery SoH data to the sitewide controller 148. If, however, the sitewide controller 148 determines that the time period for completing the worksite task has elapsed, the method 300 proceeds to operation 312.

At operation 312, the sitewide controller 148 determines a new task for the one or more mobile machines 104. The new task is determined in accordance with operation 206 discussed above and is at least in part based on the battery SoH data received at operation 308.

As discussed above, FIG. 3 depicts an example method 300 for assigning one or more mobile machines 104 at a worksite 102 to corresponding worksite tasks for a time period. Determining the duration of the time period for which one or more mobile machines 104 are assigned to tasks is done in accordance with the calculation of operation 302. The method 300 further includes generating task commands that indicate the respective worksite tasks and time periods and sending the generated task commands to the one or more mobile machines 104. The method 300 further includes receiving battery SoH data from the mobile machines 104 and determining whether the designated time period for completing the worksite tasks has elapsed. In the event that the designated time period has not yet elapsed, the method 300 includes reiteratively receiving battery SoH data from the mobile machines 104. In the event that the designated time period has elapsed, the method 300 includes determining new worksite tasks based at least in part on the battery SoH data received from the mobile machines 104 at operation 308.

It should be noted that some of the operations of method 300 may be performed out of the order presented, with additional elements, and/or without some elements. Some of the operations of method 300 may further take place substantially concurrently and, therefore, may conclude in an order different from the order of operations shown above. It should also be noted that in some cases, there may be other components of the system 100 involved in one or more of the operations, as described herein.

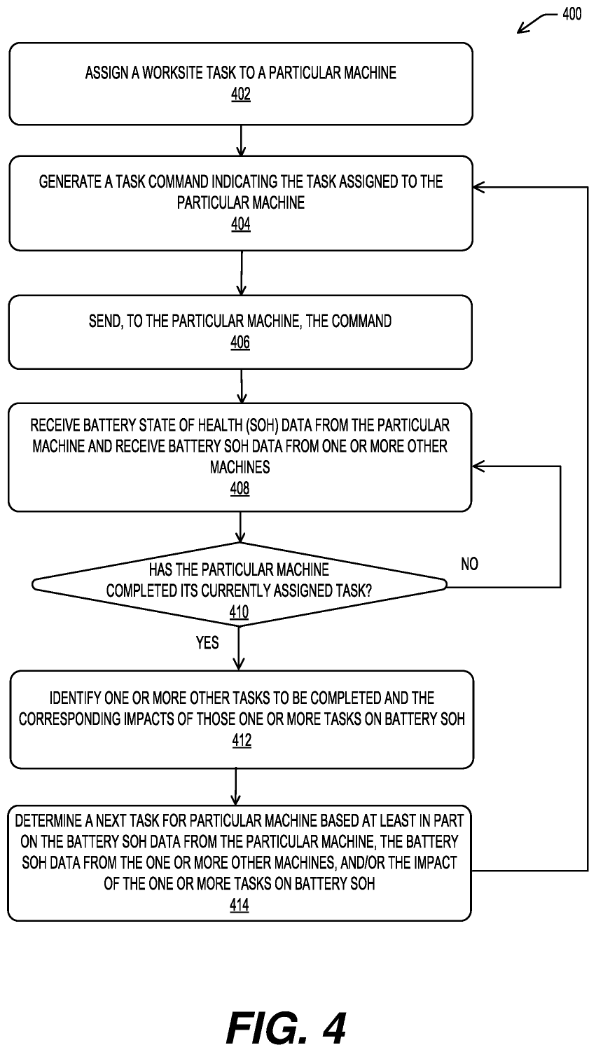

FIG. 4 illustrates a flowchart that depicts an example method 400 for assigning a worksite task to a particular mobile machine 104 of FIG. 1, and identifying one or more other worksite tasks to be completed and the corresponding impact of those tasks on battery SoH according to examples of the present disclosure. The operations of method 400 are performed by the sitewide controller 148 in cooperation with one or more entities of system 100.

At operation 402, the sitewide controller 148 assigns a worksite task to a particular mobile machine 104. As discussed herein, in some cases, a particular mobile machine 104 is one of several comparable mobile machines 104. Thus, in some cases, at operation 402 the sitewide controller 148 chooses the particular machine 104 from a subset of an inventory corresponding to the worksite 102.

At operation 404, the sitewide controller 148 generates a task command indicating the task assigned to the particular mobile machine 104. The task command includes one or more parameters associated with the worksite task that is to be completed by the mobile machine 104. The task command includes one or more data packets with header portions that indicate at least the destination mobile machine 104 is being directed to by those data packets and a threshold battery SoH required to complete the assigned worksite task. A payload portion of the data packets includes an indication of the various parameters associated with the worksite task. The parameters include at least an indication of a target battery SoH and a target battery recharging time for the mobile machine 104 upon completion of the worksite task. In other words, the payload portion of the data packets comprising the task command at least communicates to the mobile machines 104: (1) what their battery SoH should be and (2) when they should recharge their batteries upon completing a worksite task.

At operation 406, the sitewide controller 148 sends to the particular mobile machine 104 the generated task command. The task command is encoded and/or modulated onto the wireless signal 116 that is received by the antenna 118 of the mobile machine 104. The controller 114 receives the wireless signal 116 and decodes and/or demodulates the wireless signal 116 to identify the task command. In some cases, the electronic device 160, being in communication with the sitewide controller 148, requests the task command, such as based upon operator 124 input. The sitewide controller 148 transmits the task command via the wireless signal 116. In such cases, the controller 114 of the mobile machine 104 subsequently receives the task command from the sitewide controller 148 and decodes and/or demodulates the wireless signal 116 to identify the task command.

At operation 408, the sitewide controller 148 receives battery SoH data from each of the particular mobile machines 104 to which the worksite task was assigned and one or more other mobile machines 104. Because the particular mobile machine 104 has recently received a task command, the controller 114 of the particular mobile machine 104 automatically sends battery SoH data to the sitewide controller 148, such as at predetermined intervals or upon the triggering of a SoH event (e.g., upon a determination that the particular mobile machine 104 has not yet completed its currently assigned worksite task, as discussed below with regard to operation 410). In some cases, the one or more other mobile machines 104 may be offline and may not have received and/or executed task commands. Thus, the sitewide controller 148 queries the battery SoH data of one or more mobile machines 104 from which battery SoH data has not been received for a threshold time period by communicating with the controller 114 of the mobile machine 104. Alternatively, the sitewide controller 148 queries one or more mobile machines 104 that are located within a threshold vicinity of the particular mobile machine 104.

At operation 410, the sitewide controller 148 determines whether the particular mobile machine 104 has completed its currently assigned worksite task. In some cases, this determination includes a comparison of the mobile machine's 104 current battery SoH and its target battery SoH (discussed above with regard to operation 404). When a current battery SoH for a given mobile machine 104 coincides with a target battery SoH for the completion of a worksite task (and other parameters, such as the elapsing of a threshold time period are satisfied) it is determined that the particular mobile machine 104 has completed its currently assigned worksite task. Thus, this determination is initiated at least in part by receiving the battery SoH of the particular mobile machine 104 and the one or more other mobile machines 104 in operation 408. If the sitewide controller 148 determines that the particular mobile machine 104 has not completed its currently assigned worksite task (operation 410—No), the method 400 may reiteratively return to operation 408 where the particular mobile machine 104 automatically sends battery SoH data to the sitewide controller 148, and the sitewide controller 148 queries one or more other mobile machines 104 for battery SoH data. If, however, the sitewide controller 148 determines that the particular mobile machine 104 has completed its currently assigned worksite task, the method 400 proceeds to operation 412.

At operation 412, the sitewide controller 148 identifies one or more other worksite tasks to be completed and the corresponding impact of those one or more other worksite tasks on battery SoH. In some cases, the sitewide controller 148 identifies the one or more other worksite tasks to be completed in accordance with operation 206 of FIG. 2. As discussed herein, a given worksite task is in some cases expressed as a threshold battery SoH required to complete the worksite task. Thus, in some cases, the impact of a worksite task on battery SoH is expressed binarily as either an indication that the particular mobile machine 104 is suitable or not suitable to perform a next worksite task of the one or more other worksite tasks subsequent to completing a currently assigned worksite task. In other cases, the impact of the one or more other worksite tasks is considered in the aggregate, for example, as an optimized order of performance.

At operation 414, the sitewide controller 148 determines a next task for the particular mobile machine 104. Determining the next task for the particular mobile machine 104 is based at least in part on the battery SoH of the particular mobile machine 104. As discussed just above with regard to operations 408 and 412, the particular mobile machine 104 may not be suitable for performing one or more other worksite tasks, because it does not meet the threshold battery SoH. However, each of the one or more other mobile machines 104 is potentially suitable for each of the one or more other worksite tasks. Therefore, at operation 414, the sitewide controller 148 also considers battery SoH data from the one or more other mobile machines 104. Furthermore, the sitewide controller 148 (i.e., the task manager 708 and/or the battery manager 710) is configured to assign next worksite tasks to the particular mobile machine 104 in an optimized order.

As discussed above, FIG. 4 illustrates an example method 400 for assigning a worksite task to a particular mobile machine 104 and identifying one or more other worksite tasks to be completed. The operations of method 400 include assigning a worksite task to a mobile machine 104, generating a task command that indicates the assigned task, and sending the task command to the mobile machine 104. The operations of method 400 further include receiving battery SoH data from the mobile machine 104 that was assigned the worksite task, as well as one or more other mobile machines 104. Method 400 further includes operations of determining whether the mobile machine 104, to which the worksite task was assigned, has completed the currently assigned worksite task. Method 400 further includes identifying one or more other tasks to be completed at the worksite 102, such as in accordance with operation 206 of FIG. 2, and determining a next worksite task for the particular mobile machine 104 based on the received battery SoH data and an expected SoH impact of each task. As a result, and based on the operations described with respect to the method 400, the sitewide controller is able to determine the order in which the mobile machine 104 should perform available worksite tasks.

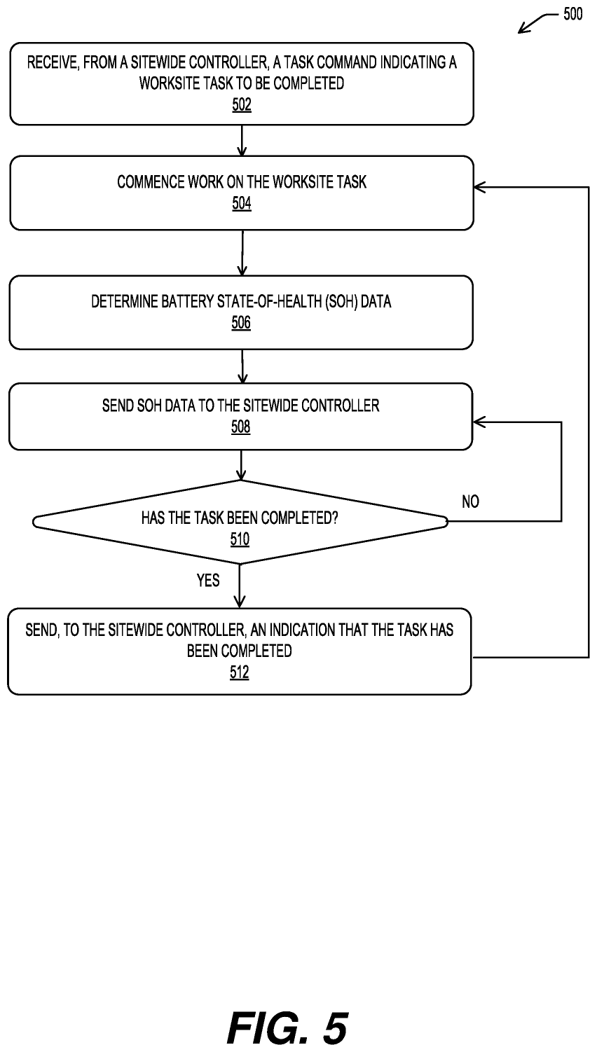

FIG. 5 illustrates a flowchart that depicts an example method 500 for receiving a task command, completing the task, and indicating that the task has been completed.

At operation 502, the controller 114 of a mobile machine 104 receives, from the sitewide controller 148, a task command indicating a worksite task to be completed. As discussed herein, in some cases, a particular mobile machine 104 is one of several comparable mobile machines 104. Thus, in some cases, at operation 402 the sitewide controller 148 chooses the particular mobile machine 104 from a subset of an inventory corresponding to the worksite 102. As discussed herein, the task command includes one or more parameters associated with the worksite task that is to be completed by the mobile machine 104.

At operation 504, the controller 114 of the mobile machine 104 causes the mobile machine 104 to commence work on the assigned worksite task. This may include relocating to a location at the worksite 102 that is associated with a worksite task, ascertaining a two-dimensional or three-dimensional area associated with the location of the worksite task, performing one or more predefined or predetermined operations, etc. In some cases, this commencement is initiated by receiving from the sitewide controller 148 an initiation command.

At operation 506, the controller 114 of the mobile machine 104 determines battery SoH data for the mobile machine 104. As described herein, determination of battery SoH is achieved in accordance with operation 208 of FIG. 2. In some cases, battery SoH data is first SoH data corresponding directly to one or more battery SoH metrics (e.g., cycle DoD, battery SoC, etc.). In other cases, battery SoH data is second SoH data derived from the one or more battery SoH metrics.

At operation 508, the controller 114 of the mobile machine 104 sends the battery SoH data to the sitewide controller 148. As discussed above with regard to operation 506, the controller 114 sends either first SoH data, second SoH data, or some combination thereof. In some cases, it is advantageous to send processed battery SoH data (i.e., second SOH data) to optimize bandwidth considerations.

At operation 510, the controller 114 of the mobile machine 104 determines whether the assigned worksite task has been completed. This determination is initiated at least in part by sending the battery SoH data of the particular mobile machine 104 in operation 508. In some example cases, the controller 114 is configured to parse the battery SoH data (e.g., in association with sending the battery SoH data to the sitewide controller 148) to determine whether current SoH data coincides with target SoH data as discussed above. In at least some cases, the controller 114 is further configured to parse sensor data of the one or more sensors 120 for indications that the mobile machine 104 has completed its currently assigned worksite task. For example, the controller 114 of the mobile machine 104 is configured to parse infrared data to ascertain the size of the two-dimensional or three-dimensional area associated with the location of the worksite task. The controller 114 of the mobile machine 104 is further configured to parse GPS and/or propulsion data of the propulsion system 122 to ascertain whether/how many times the mobile machine 104 has traversed the two-dimensional or three-dimensional area associated with the worksite task.

If the controller 114 determines that the particular mobile machine 104 has not completed its currently assigned worksite task (operation 510—No), the method 500 may reiteratively return to operation 508 where the particular mobile machine 104 automatically sends battery SoH data to the sitewide controller 148. If, however, the controller 114 determines that the particular mobile machine 104 has completed its currently assigned worksite task (operation 510— Yes), the method 500 proceeds to operation 512.

At operation 512, the controller 114 of the mobile machine 104 sends the sitewide controller 148 an indication that the current worksite task has been completed. In some cases, operation 512 proceeds immediately and automatically upon a determination by the controller 114 that the mobile machine 104 has completed its current worksite task. In other cases, the controller 114 receives (e.g., from the sitewide controller 148) a completion status request. In such cases, the controller 114 may provide an appropriate completion status such as “in progress” or the like, in addition to “complete.”

As discussed, FIG. 5 depicts an example method 500 for receiving a task command, completing the worksite task, and indicating that the worksite task has been completed. Method 500 includes receiving, by the controller 114 of the mobile machine 104 from the sitewide controller 148, a task command. Method 500 further includes the mobile machine 104 commencing work on the worksite task. Method 500 further includes the controller 114 of the mobile machine 104 determining battery SoH for the mobile machine 104. Method 500 further includes sending the battery SoH data to the sitewide controller 148 and determining whether the assigned worksite task has been completed. In some cases, method 500 includes parsing the battery SoH data in association with sending it to the sitewide controller 148 to determine whether the worksite task has been completed. Method 500 further includes sending the sitewide controller 148 an indication that the worksite task has been completed. As a result, and based on the operations described with respect to the method 500, the controller 114 is able to ensure that the mobile machine 14, after having received a task command, completes said worksite task and reports SoH data conducive for balancing battery SoH throughout the completion of various next worksite tasks.

FIG. 6 illustrates exemplary quantities considered when determining an impact on battery SoH. In some cases, one or more of cycle DoD, lifetime battery energy throughput, battery SoC, battery chemistry, battery charging/discharging C-rate, and battery temperature are weighted equally in calculating battery SoH. In other cases, certain of these quantities are weighted more substantially than others based on relevant factors such as battery type.

FIG. 7 is a block diagram of an example sitewide controller 148 that implements worksite tasks of the mobile machines 104 depicted in FIG. 1, according to examples of the present disclosure. In some cases, there are multiple sitewide controllers 148 that perform the operations, as discussed herein. In those cases, the other sitewide controllers 148 cooperate with and are similar to the sitewide controller 148 and enable the mobile machines 104 to function as described herein. The sitewide controller 148 includes one or more processor(s) 152, one or more communication interface(s) 702, and computer-readable media 154.

In some implementations, the processors(s) 152 may include a central processing unit (CPU), a graphics processing unit (GPU), both a CPU and GPU, a microprocessor, a digital signal processor or other processing units or components known in the art. Alternatively, or in addition, the functionally described herein can be performed, at least in part, by one or more hardware logic components. For example, and without limitation, illustrative types of hardware logic components that may be used include field-programmable gate arrays (FPGAs), application-specific integrated circuits (ASICs), application-specific standard products (ASSPs), system-on-a-chip systems (SOCs), complex programmable logic devices (CPLDs), etc. Additionally, each of the processor(s) 700 may possess its own local memory, which also may store program modules, program data, and/or one or more operating systems. The one or more processor(s) 152 may include one or more cores.

The communications interface(s) 702 may enable the sitewide controller 148 to communicate via the one or more network(s), such as via the wireless signals 116. The communications interface(s) 702 may include a combination of hardware, software, and/or firmware and may include software drivers for enabling any variety of protocol-based communications, and any variety of wireline and/or wireless ports/antennas. For example, the communications interface(s) 702 may comprise one or more of WiFi, cellular radio, a wireless (e.g., IEEE 802.1x-based) interface, a Bluetooth® interface, and the like. In some cases, if a remote control is used to control the mobile machine 104, the communications interface(s) 702 may enable the use of remote-control signals to communicate with the mobile machine 104. The sitewide controller 148 is configured to receive data from the mobile machine 104 to determine state characteristics such as operational modes as well as the present location of the mobile machine 104.

The computer-readable media 154 may include volatile and/or nonvolatile memory, removable and non-removable media implemented in any method or technology for storage of information, such as computer-readable instructions, data structures, program modules, or other data. Such memory includes, but is not limited to, RAM, ROM, EEPROM, flash memory or other memory technology, CD-ROM, digital versatile discs (DVD) or other optical storage, magnetic cassettes, magnetic tape, magnetic disk storage or other magnetic storage devices, RAID storage systems, or any other medium which can be used to store the desired information and which can be accessed by a computing device. The computer-readable media 154 may be implemented as computer-readable storage media (CRSM), which may be any available physical media accessible by the processor(s) 152 to execute instructions stored on the computer-readable media 154. In one basic implementation, CRSM may include random access memory (RAM) and Flash memory. In other implementations, CRSM may include, but is not limited to, read-only memory (ROM), electrically erasable programmable read-only memory (EEPROM), or any other tangible medium which can be used to store the desired information, and which can be accessed by the processor(s) 152. The computer-readable media 154 may have an operating system (OS) and/or a variety of suitable applications stored thereon. The OS, when executed by the processor(s) 152 may enable management of hardware and/or software resources of the controller 114.

Several components such as instruction, data stores, and the like may be stored within the computer-readable media 154 and configured to execute on the processor(s) 152. The computer-readable media 154 may have stored thereon a battery manager 156, a task manager 158, a command manager 159, and an implementation of the sitewide model 162 described herein. It will be appreciated that each of the components 156, 158, and 159 may have instructions stored thereon that when executed by the processor(s) 152 may enable various functions pertaining to completion of worksite tasks by the mobile machine 104, as described herein.

The instructions stored in the battery manager 156, when executed by the processor(s) 152, configure the sitewide controller 148 to at least receive battery SoH data, monitor and/or parse the received battery SoH data, generate secondary SoH data based on the received battery SoH data, and initiate balancing of one or more batteries of the machines 104. Further, the battery manager 156 is configured to perform analogous functions to the SoH manager 164 described herein.

The instructions stored in the task manager 158, when executed by the processor(s) 152, configures the sitewide controller 148 to identify tasks associated with the worksite 102.

The instructions stored in the command manager 159, when executed by the processor(s) 700, configure the sitewide controller 148 to generate task commands. Thus, the command manager 706 is configured to perform various functions pertaining to formatting data packets having header and payload information conducive to instruct mobile machines 104 to complete worksite tasks.

FIG. 8 is a block diagram of an example electronic device 160 for balancing battery SoH across a fleet of mobile machines 104 at a worksite 102, according to examples of the present disclosure. The hardware and software, as discussed herein, may be an implementation of the sitewide model 162 of the electronic device 160. In some cases, there may be multiple electronic devices 160 at a worksite 102, as discussed herein. In those cases, the other electronic device(s) 160 may be similar to the electronic device 160, as described herein. The electronic device 160 includes one or more processor(s) 108, one or more communication interface(s) 802, and computer-readable media 110. The descriptions of the one or more processor(s) 108, the one or more communication interface(s) 802, and the computer-readable media 110 may be substantially similar to the descriptions of the one or more processor(s) 152, the one or more communication interface(s) 702, and the computer-readable media 154, as described in conjunction with FIGS. 1 and 7 herein, and in the interest of brevity, will not be repeated here.

Several components such as instruction, data stores, and the like may be stored within the computer-readable media 110 and configured to execute on the processor(s) 108. The computer-readable media 110 may have stored thereon a sitewide model 162, a SoH manager 164, and a task command manager 166. It will be appreciated that each of the components 162, 164, and 166 may have instructions stored thereon that when executed by the processor(s) 108 may enable various functions pertaining to completion of worksite tasks by the mobile machine 104 and balancing of battery SoH, as described herein.

The instructions stored in the sitewide model 162, when executed by the processor(s) 108, configure the electronic device 160 to identify the mobile machines 104 at a worksite 102. The electronic device 160 determines various battery parameters of the mobile machines 104, including but not limited to battery SoH, battery SoC, battery age, and target battery planned replacement. Based on these various battery parameters, the electronic device 160 correlates one or more worksite tasks to particular mobile machines 104. The electronic device 160 is further configured to identify the current positions of each of the mobile machines 104 at the worksite 102 and display the same to an operator 124, such as in the form of a map, in order to facilitate dispatching mobile machines 104 to the locations of their respective worksite tasks.

The instructions stored in the SoH manager 164, when executed by the processor(s) 108, configures the electronic device 160 to query a mobile machine 104 for battery SoH data. The SoH manager 164 is further configured to process, clean, parse, etc. raw or first battery SoH data into a format suitable for use according to the present disclosure.

The instructions stored in the task command manager 166, when executed by the processor(s) 108, configures the electronic device 160 to generate a task command that provides one or more parameters to instruct a worksite task of a mobile machine 104. In some cases, the electronic device 160, via the task command, instructs a mobile machine 104 to autonomously proceed to a final destination. In other cases, the electronic device 160 instructs a mobile machine 104 to follow another machine and/or pilot vehicle to a final destination. In yet other cases, such as when the mobile machine 104 is non-autonomous, the task command is sent to the machine operator via radio or a display in the cab of the mobile machine 104 to execute the work assignment. The instructions stored in the task command manager 166, when executed by the processor(s) 108, further configures the electronic device 160 to receive, such as from a controller 114 of a mobile machine 104, an indication that a worksite task has been completed. The electronic device 160 is configured to provide an indication, such as on a display of the electronic device 160 to be viewed by the operator 124, that the assigned worksite task has been completed.

### INDUSTRIAL APPLICABILITY

A work site typically has a plurality of the same types of machine working in various applications to fulfill a productivity requirement. The harshness of the various machine applications on a given work site may lead to lower than expected productivity and reliability. For example, the similar types of machines operating in different applications across the site may experience varied battery lives, causing the potential for increased downtime and operating costs on a fleet of similar machines as compared to different machines.

As disclosed herein, a sitewide model proactively tracks the work history and current battery SoH of each machine to determine task assignments such that the machines rotate through the various applications on a periodic basis. Additionally, the model ensures a sufficient battery SoH to complete the assigned task. Balancing battery SoH across the fleet results in more consistent operation and productivity. In other words, mobile machines 104 that perform construction, mining, farming, and other activities may be assigned appropriate tasks at the worksite 102 to promote battery health and longevity with greater accuracy than traditional methods and facilitate more predictable maintenance and battery replacement intervals.

In a non-limiting application of the technologies described herein, consider a large mining operation with various mineral extraction points and dozens of mobile machines 104 at the worksite 102. In such an operation, an example productivity metric may include the rate at which to extract the mineral for each extraction point. An increased extraction speed can be desirable, but the opportunity cost of increased extraction speed should be balanced against the cost of depleting the batteries of the mobile machines 104. The technologies described herein can optimize these types of worksite tasks. This may allow the mobile machines 104 at a worksite 102 to be used more efficiently and with less human introduced error. This can reduce the labor costs associated with the considerable amount of energy required to recharge/refuel the mobile machines 104 at a worksite 102. For example, ad hoc assignment of mobile machines 104 to worksite tasks leads to inefficient recharging/refueling schedules. During this time, the mobile machine 104 may be sitting idle and may further be wasting energy/fuel and hours awaiting maintenance. Using the technologies disclosed herein, the idle time of these mobile machines 104 may be reduced and/or eliminated. Additionally, the mobile machines 104 may be serviced, recharged, refueled, maintained, etc. on a more precise schedule than human operators can enable. Thus, the technologies described herein not only reduce human oversight and associated costs at a worksite 102, but can also reduce the idle time, reduce fuel consumption, and increase efficiency and engagement of the mobile machines 104 at the worksite 102.

While aspects of the present disclosure have been particularly shown and described with reference to the embodiments above, it will be understood by those skilled in the art that various additional embodiments may be contemplated by the modification of the disclosed machines, systems and methods without departing from the spirit and scope of what is disclosed. Such embodiments should be understood to fall within the scope of the present disclosure as determined based upon the claims and any equivalents thereof.

Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein.

1. A sitewide controller, comprising:
one or more processors; and
one or more non-transitory computer-readable media storing computer-executable instructions that, when executed, cause the one or more processors to perform operations comprising:
identifying one or more machines associated with a worksite;
determining a first battery state-of-health (SoH) of a first battery associated with a first machine;
determining a second battery SoH of a second battery associated with a second machine;
identifying one or more worksite tasks to be performed at the worksite;
determining, for each worksite task of the one or more worksite tasks, a first predicted impact on the first SoH and a second predicted impact on the second SoH;
assigning, based at least in part on the first SoH, the second SoH, the first predicted impact corresponding to a first worksite task of the one or more worksite tasks, and the second predicted impact corresponding to a second worksite task of the one or more worksite tasks, the first worksite task to the first machine, wherein assigning the first worksite task to the first machine indicates a lower predicted impact on the first SoH;
assigning, based at least in part on the first SoH, the second SoH, the first predicted impact corresponding to the first worksite task, and the second predicted impact corresponding to the second worksite task, the second worksite task to the second machine, wherein assigning the second worksite task to the second machine indicates a lower predicted impact on the second SoH;
generating a first task command indicating the first worksite task corresponding to the first machine;
generating a second task command indicating the second worksite task corresponding to the second machine;
sending, to the first machine, the first task command indicating the first worksite task; and
sending, to the second machine, the second task command indicating the second worksite task.

2. The sitewide controller of claim 1, further comprising:
a communications interface, wherein the communications interface enables wirelessly receiving first battery SoH data from the first machine and sending the first task command to the first machine.

3. The sitewide controller of claim 2, further comprising:
a battery manager, wherein the battery manager at least enables parsing of battery SoH data and generation of secondary SoH data.

4. The sitewide controller of claim 2, further comprising:
a command manager, wherein the command manager enables generation of task commands indicating at least a worksite task destination, a target battery SoH, and a target battery replacement time.

5. The sitewide controller of claim 1, wherein determining that the second worksite task is to be assigned to the second machine further comprises:
determining a first target battery SoH of the first battery upon completion of the first worksite task;
determining a second target battery SoH of the first battery upon completion of the second worksite task;
determining a third target battery SoH of the second battery upon completion of the second worksite task;
determining a fourth target battery SoH of the second battery upon completion of the first worksite task; and
determining that a first difference between the first target battery SoH and the third target battery SoH is less than a second difference between the second target battery SoH and the fourth target battery SoH.

6. The sitewide controller of claim 1, wherein the operations further comprise:
determining that the first machine has completed the first worksite task;
identifying one or more other worksite tasks to be completed;
determining, for each worksite task of the one or more worksite tasks, a predicted impact on the first battery SoH; and
determining that the first machine is to be assigned a third worksite task of the one or more other worksite tasks based at least in part on the predicted impacts on the first battery SoH, wherein assigning the third worksite task to the first machine indicates a lower predicted impact of the third worksite task on the first battery SoH than corresponding predicted impacts of others of the one or more other worksite tasks.

7. The sitewide controller of claim 1, wherein the operations further comprise:
determining that a first time period for completing the first worksite task and the second worksite task has elapsed;
determining a third battery SoH associated with the first battery;
determining a fourth battery SoH associated with the second battery;
determining that the first machine is to be assigned a third worksite task of the one or more worksite tasks based at least in part on the third battery SoH and the fourth battery SoH; and
determining that the second machine is to be assigned a fourth worksite task of the one or more worksite tasks based at least in part on the third battery SoH and the fourth battery SoH, wherein the first machine performing the third worksite task during a second time period and the second machine performing the fourth worksite task during the second time period optimizes a fifth target SoH of the first battery and a sixth target SOH of the second battery.

8. The sitewide controller of claim 1, wherein the operations further comprise:
identifying a sitewide project;
determining, using a sitewide model and based at least in part on the sitewide project, the one or more worksite tasks; and
indexing the one or more worksite tasks according to predicted impact on battery SoH.

9. The sitewide controller of claim 8, wherein the operations further comprise normalizing the one or more worksite tasks according to predicted impact on battery SoH.

10. The sitewide controller of claim 1, wherein the operations further comprise:
determining a third battery SoH of a third battery associated with a third machine;
determining, based at least in part on the first battery SoH, the second battery SoH, and the third battery SoH, that a third worksite task of the one or more worksite tasks is to be assigned to the third machine; and
sending, to the third machine, a third task command indicating the third worksite task.

11. A method, comprising:
identifying one or more machines associated with a worksite;
determining a first battery state-of-health (SoH) of a first battery associated with a first machine;
determining a second battery SoH of a second battery associated with a second machine;
identifying one or more worksite tasks to be performed at the worksite;
determining, for each worksite task of the one or more worksite tasks, a first predicted impact on the first battery SoH and a second predicted impact on the second battery SoH;
assigning, based at least in part on the first battery SoH, the second battery SoH, the first predicted impact corresponding to a first worksite task of the one or more worksite tasks, and the second predicted impact corresponding to a second worksite task of the one or more worksite tasks, the first worksite task to the first machine, wherein assigning the first worksite task to the first machine indicates a lower predicted impact on the first battery SoH;
assigning, based at least in part on the first battery SoH, the second battery SoH, the first predicted impact corresponding to the first worksite task, and the second predicted impact corresponding to the second worksite task, the second worksite task to the second machine, wherein assigning the second worksite task to the second machine indicates a lower predicted impact on the second battery SoH;
generating a first task command indicating the first worksite task corresponding to the first machine;
generating a second task command indicating the second worksite task corresponding to the second machine;
sending, to the first machine, the first task command indicating the first worksite task; and
sending, to the second machine, the second task command indicating the second worksite task.

12. The method of claim 11, further comprising:
determining that the first machine has completed the first worksite task;
identifying one or more other worksite tasks to be completed;
determining, for each worksite task of the one or more worksite tasks, a predicted impact on the first battery SoH; and
determining that the first machine is to be assigned a third worksite task of the one or more other worksite tasks based at least in part on the predicted impacts on the first battery SoH, wherein assigning the third worksite task to the first machine indicates a lower predicted impact of the third worksite task on the first battery SoH than corresponding predicted impacts of others of the one or more other worksite tasks.

13. The method of claim 11, further comprising:
determining that a first time period for completing the first worksite task and the second worksite task has elapsed;
determining a third battery SoH associated with the first battery;
determining a fourth battery SoH associated with the second battery;
determining that the first machine is to be assigned a third worksite task of the one or more worksite tasks based at least in part on the third battery SoH and the fourth battery SoH; and
determining that the second machine is to be assigned a fourth worksite task of the one or more worksite tasks based at least in part on the third battery SoH and the fourth battery SoH, wherein the first machine performing the third worksite task during a second time period and the second machine performing the fourth worksite task during the second time period balances a first target SoH of the first battery and a second target SoH of the second battery.

14. The method of claim 11, wherein predicted impact on battery SoH is based on at least one of: (i) cycle depth of discharge; (ii) lifetime energy throughput; (iii) state of charge; (iv) physical or chemical battery properties; or (v) battery temperature, battery chemistry, charge and discharge rates or any other relevant parameters.

15. The method of claim 11, further comprising:
receiving, from one or more other machines and via a communications interface, first battery SoH data associated with one or more batteries of the one or more other machines; and
generating secondary battery SoH data based on the first battery SoH data.

16. The method of claim 11, further comprising:
identifying a sitewide project;
determining, using a sitewide model and based at least in part on the sitewide project, the one or more worksite tasks; and
indexing the one or more worksite tasks according to predicted impact on battery SoH.

17. The method of claim 11, further comprising normalizing the one or more worksite tasks according to predicted impact on battery SoH.

18. A machine comprising:
a battery;
one or more processors; and
one or more non-transitory computer-readable media storing computer-executable instructions that, when executed, cause the one or more processors to perform operations comprising:
receiving, from a sitewide controller, a first task command indicating a first worksite task to be completed;
ascertaining, based at least in part on the first task command, a two-dimensional area or a three-dimensional volume associated with a location of the first worksite task;
causing, based at least in part on the first task command, the machine to commence work on the first worksite task;
determining that the first worksite task is complete;
determining a first battery state of health (SoH) associated with the battery upon completion of the first worksite task;
sending, to the sitewide controller, a first indication of SoH data associated with the battery;
sending, to the sitewide controller, an indication that the first worksite task has been completed; and
receiving, from the sitewide controller, a second task command indicating a second worksite task to be completed, wherein the second task command is generated based at least in part on the second worksite task balancing a predicted impact on the first battery SoH compared with other available worksite tasks.

19. The machine of claim 18, wherein the second worksite task to be completed by the machine is based at least in part on battery SoH data associated with a second machine.

20. The machine of claim 18, further comprising:
determining that the first worksite task is incomplete; and
sending, to the sitewide controller and based at least in part on determining that the first worksite task is incomplete, a second indication of SoH data associated with the battery.
